(19) United States
(12) Patent Application Publication
(10) Pub. No.: US 2025/0246141 A1
(43) Pub. Date: Jul. 31, 2025

(54) DISPLAY DEVICE

(71) Applicant: Samsung Display Co., Ltd., Yongin-si (KR)

(72) Inventors: Daehyun KIM, Yongin-si (KR); SUNGHWAN KIM, Yongin-si (KR); KYOUNGJIN PARK, Yongin-si (KR); JUYONG PARK, Yongin-si (KR); YOUNGGUG SEOL, Yongin-si (KR); Minki YANG, Yongin-si (KR); CHANGKYU JIN, Yongin-si (KR)

(21) Appl. No.: 18/928,410

(22) Filed: Oct. 28, 2024

(30) Foreign Application Priority Data
Jan. 26, 2024 (KR) 10-2024-0012605
Mar. 26, 2024 (KR) 10-2024-0041072

(51) Int. Cl. G09G 3/3233; H10K 59/121; H10K 59/131

(52) U.S. Cl. CPC G09G 3/3233; H10K 59/1216; H10K 59/131; G09G 2300/0426; G09G 2300/0852

(57) ABSTRACT

A display device includes a scan line extending in a first direction, where the scan line includes a write scan line and a bias scan line, a data line extending in a second direction crossing the first direction, and a pixel connected to the scan line and the data line. The bias scan line includes a plurality of sub-bias scan lines spaced apart from each other in the first direction and a connecting line connected to the sub-bias scan lines.

This application claims priority to Korean Patent Application No. 10-2024-0012605, filed on Jan. 26, 2024, and Korean Patent Application No. 10-2024-0041072, filed on Mar. 26, 2024, and all the benefits accruing therefrom under 35 U.S.C. § 119, the contents of which in their entireties are incorporated by reference.

### BACKGROUND

### (1) Field

Embodiments of the disclosure described herein relate to a display device.

### (2) Description of the Related Art

In general, electronic devices, such as a smart phone, a digital camera, a notebook computer, a car navigation unit, a smart television, and the like, which provide an image to a user, may include a display device for displaying an image. Such display devices may generate an image and provide the generated image to the user through a display screen.

The display device typically includes a plurality of pixels for generating an image and a driver for driving the pixels. Each of the pixels may include a light emitting element, a plurality of transistors connected to the light emitting element, and at least one capacitor connected to the transistors. The transistors are connected to a scan line, a data line, and a light emission line. The transistors are driven by a scan signal, a data voltage, and a light emission signal applied through the scan line, the data line, and the light emission line.

### SUMMARY

When transistors of a display device are manufactured, a doping process may be performed on semiconductor layers of the transistors. In the doping process, a phenomenon in which charges are concentrated on a scan line may occur, and static electricity may be generated from the scan line. The semiconductor layers of the transistor may be damaged by the static electricity. Accordingly, a technology for reducing the static electricity is desired.

Embodiments of the disclosure provide a display device in which damage to pixels is effectively prevented by reducing static electricity generated from a bias scan line.

According to an embodiment, a display device includes a scan line extending in a first direction, where the scan line includes a write scan line and a bias scan line, a data line extending in a second direction crossing the first direction, and a pixel connected to the scan line and the data line. In such an embodiment, the bias scan line includes a plurality of sub-bias scan lines spaced apart from each other in the first direction and a connecting line connected to the sub-bias scan lines.

According to an embodiment, a display device includes a scan line extending in a first direction, where the scan line includes a write scan line and a bias scan line, a plurality of data lines extending in a second direction crossing the first direction, and a plurality of pixels arranged in the first direction and connected to the scan line and the data lines. In such an embodiment, the bias scan line includes a plurality of sub-bias scan lines spaced apart from each other for at least one pixel and a plurality of connecting lines connected to the sub-bias scan lines.

According to an embodiment, a display device includes a scan line

extending in a first direction, where the scan line includes a write scan line and a bias scan line, a data line extending in a second direction crossing the first direction, and a pixel connected to the scan line and the data line. In such an embodiment, the bias scan line includes two sub-bias scan lines spaced apart from each other in the first direction and a connecting line connected to the two sub-bias scan lines. In such an embodiment, the pixel includes a plurality of transistors connected to the data line, the write scan line, and the bias scan line and a light emitting element connected to a corresponding transistor among the transistors. In such an embodiment, the two sub-bias scan lines are disposed in a same layer as gate electrodes of the transistors, and the connecting line is disposed above the gate electrodes.

### BRIEF DESCRIPTION OF THE DRAWINGS

The above and other features of embodiments of the disclosure will become apparent by describing in detail embodiments thereof with reference to the accompanying drawings, in which:

FIG. 1 is a perspective view of a display device according to an embodiment of the disclosure;

FIG. 2 is a sectional view of the display device illustrated in FIG. 1;

FIG. 3 is a sectional view of a display panel illustrated in FIG. 2;

FIG. 4 is a plan view of the display panel illustrated in FIG. 3;

FIG. 5 is a view illustrating an equivalent circuit of one pixel illustrated in FIG. 4;

FIG. 6 is a signal timing diagram of signals for driving the pixel illustrated in FIG. 5;

FIG. 7 is a sectional view illustrating a light emitting element, a first transistor, and a sixth transistor of the pixel illustrated in FIG. 5;

FIGS. 8A to 8E are views illustrating a planar structure of the pixel illustrated in FIG. 5 in a layer-by-layer manner;

FIG. 9 is a schematic plan view illustrating pixels arranged in one row and a bias scan line;

FIG. 10 is a view illustrating only a plurality of bias scan lines in the display panel;

FIGS. 11 and 12 are views illustrating components of bias scan lines according to embodiments of the disclosure;

FIG. 13 is a sectional view taken along line I-I′ illustrated in FIG. 8D;

FIG. 14 is a view for explaining a doping process for a semiconductor layer;

FIG. 15 is a view illustrating a doping process performed in a state in which sub-bias scan lines of the disclosure are disposed on a substrate;

FIG. 16 is a view illustrating a doping process performed in a state in which a comparative bias scan line is disposed on a substrate; and

FIGS. 17 to 19 are views illustrating components of bias scan lines according to various embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, when it is mentioned that a component (or an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

In addition, terms such as “below”, “under”, “above”, and “over” are used to describe a relationship of components illustrated in the drawings. The terms are relative concepts and are described based on directions illustrated in the drawing.

Unless otherwise defined, all terms used herein, including technical or scientific terms, have the same meanings as those generally understood by those skilled in the art to which the disclosure pertains. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

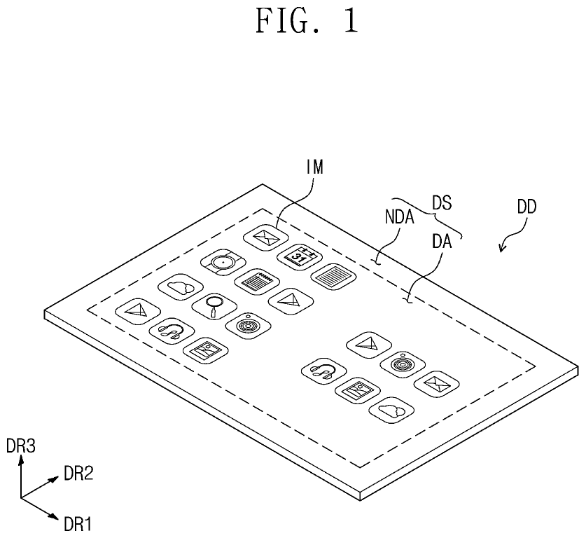

FIG. 1 is a perspective view of a display device according to an embodiment of the disclosure.

Referring to FIG. 1, an embodiment of the display device DD may have surface on a plane defined by a first direction DR1 and a second direction DR2 crossing each other. The display device DD may have a rectangular shape with long sides extending in the first direction DR1 and short sides extending in the second direction DR2 in a plan view or when viewed in a third direction DR3. However, without being limited thereto, the display device DD may have one of other various shapes such as a circular shape, a polygonal shape, and the like.

Hereinafter, a direction substantially perpendicular to the plane defined by the first direction DR1 and the second direction DR2 or a thickness direction of the display device DD is defined as the third direction DR3. In addition, the expression “when viewed from above the plane” or “in a plan view” used herein may mean that it is viewed in the third direction DR3.

The upper surface of the display device DD may be defined as a display surface DS and may be on a plane defined by the first direction DR1 and the second direction DR2. Images IM generated by the display device DD may be provided to a user through the display surface DS.

The display surface DS may include a display area DA and a non-display area NDA around the display area DA. The display area DA may display an image, and the non-display area NDA may not display any image. The non-display area NDA may surround the display area DA and may define the border of the display device DD that is printed in a certain color.

The display device DD according to an embodiment may be used in electronic devices, such as a smart phone, a digital camera, a notebook computer, a monitor, a smart television, and a car navigation unit, which provide an image to the user.

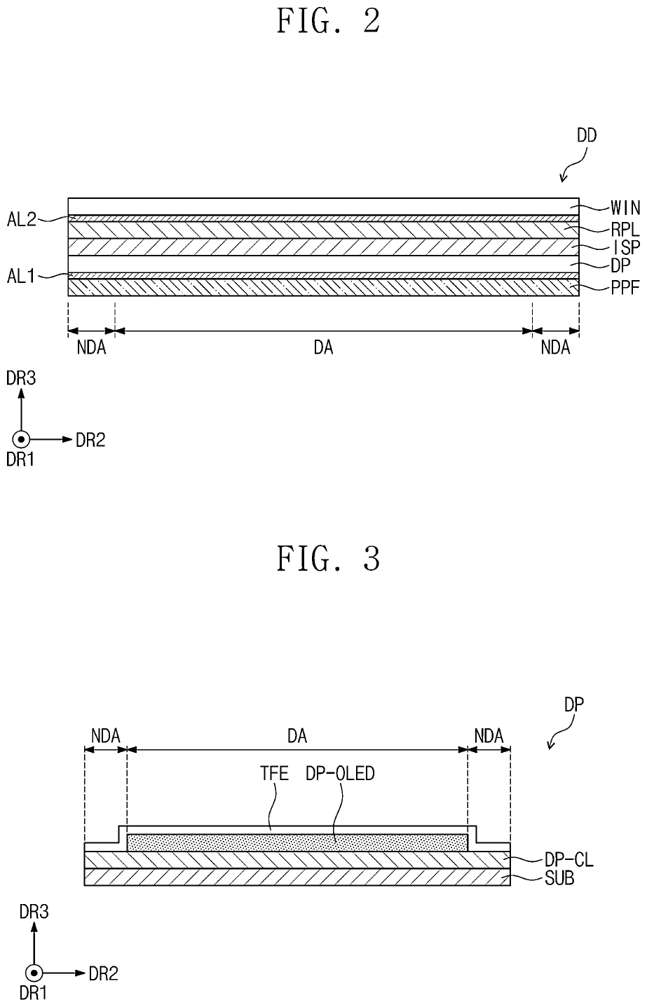

FIG. 2 is a sectional view of the display device illustrated in FIG. 1.

In FIG. 2, a section of the display device DD viewed in the first direction DR1 is illustrated.

Referring to FIG. 2, an embodiment of the display device DD may include a display panel DP, an input sensing part ISP, an anti-reflective layer RPL, a window WIN, a panel protection film PPF, and first and second adhesive layers AL1 and AL2.

The display panel DP according to an embodiment of the disclosure may be an emissive display panel. In an embodiment, for example, the display panel DP may be an organic light emitting display panel or an inorganic light emitting display panel. An emissive layer of the organic light emitting display panel may include an organic luminescent material. An emissive layer of the inorganic light emitting display panel may include quantum dots, quantum rods, or the like. Hereinafter, for convenience of description, embodiments where the display panel DP is an organic light emitting display panel will be mainly described, but not being limited thereto.

The input sensing part ISP may be disposed on the display panel DP. The input sensing part ISP may include a plurality of sensing parts (not illustrated) for sensing an external input in a capacitive type. In an embodiment, the input sensing part ISP may be directly manufactured on the display panel DP when the display device DD is manufactured. Alternatively, without being limited thereto, the input sensing part ISP may be manufactured as a panel separate from the display panel DP and may be attached to the display panel DP by an adhesive layer.

The anti-reflective layer RPL may be disposed on the input sensing part ISP. In an embodiment, the anti-reflective layer RPL may be directly manufactured on the input sensing part ISP when the display device DD is manufactured. Alternatively, without being limited thereto, the anti-reflective layer RPL may be manufactured as a separate panel and may be attached to the input sensing part ISP by an adhesive layer.

The anti-reflective layer RPL may be defined as a film for preventing reflection of external light. The anti-reflective layer RPL may decrease the reflectance of external light incident toward the display panel DP from above the display device DD. Due to the anti-reflective layer RPL, the reflected external light may not be visible to the user.

When external light travelling toward the display panel DP is reflected from the display panel DP and provided back to the user, the user may visually recognize the external light as in a mirror. In an embodiment, the anti-reflective layer RPL may include a plurality of color filters that display the same colors as those of pixels of the display panel DP to prevent such a phenomenon.

The color filters may filter the external light into the same colors as those of the pixels. In such an embodiment, the external light may not be visible to the user. Alternatively, without being limited thereto, the anti-reflective layer RPL may include a phase retarder and/or a polarizer to decrease the reflectance of the external light.

The window WIN may be disposed on the anti-reflective layer RPL. The window WIN may protect the display panel DP, the input sensing part ISP, and the anti-reflective layer RPL from external scratches and impacts.

The panel protection film PPF may be disposed under the display panel DP. The panel protection film PPF may protect a lower portion of the display panel DP. The panel protection film PPF may include a flexible plastic material such as polyethylene terephthalate (PET).

The first adhesive layer AL1 may be disposed between the display panel DP and the panel protection film PPF, and the display panel DP and the panel protection film PPF may be bonded to each other by the first adhesive layer AL1. The second adhesive layer AL2 may be disposed between the window WIN and the anti-reflective layer RPL, and the window WIN and the anti-reflective layer RPL may be bonded to each other by the second adhesive layer AL2.

FIG. 3 is a sectional view of the display panel illustrated in FIG. 2.

In FIG. 3, a section of the display panel DP viewed in the first direction DR1 is illustrated.

Referring to FIG. 3, an embodiment of the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display area DA and a non-display area NDA around the display area DA. The substrate SUB may include glass or may include a flexible plastic material such as polyimide (PI). The display element layer DP-OLED may be disposed on the display area DA.

A plurality of pixels may be disposed in the circuit element layer DP-CL and the display element layer DP-OLED. Each of the pixels may include transistors disposed in the circuit element layer DP-CL and a light emitting element disposed in the display element layer DP-OLED and connected to the transistors.

The thin film encapsulation layer TFE may be disposed on the circuit element layer DP-CL to cover the display element layer DP-OLED. The thin film encapsulation layer TFE may protect the pixels from moisture, oxygen, and external foreign matter.

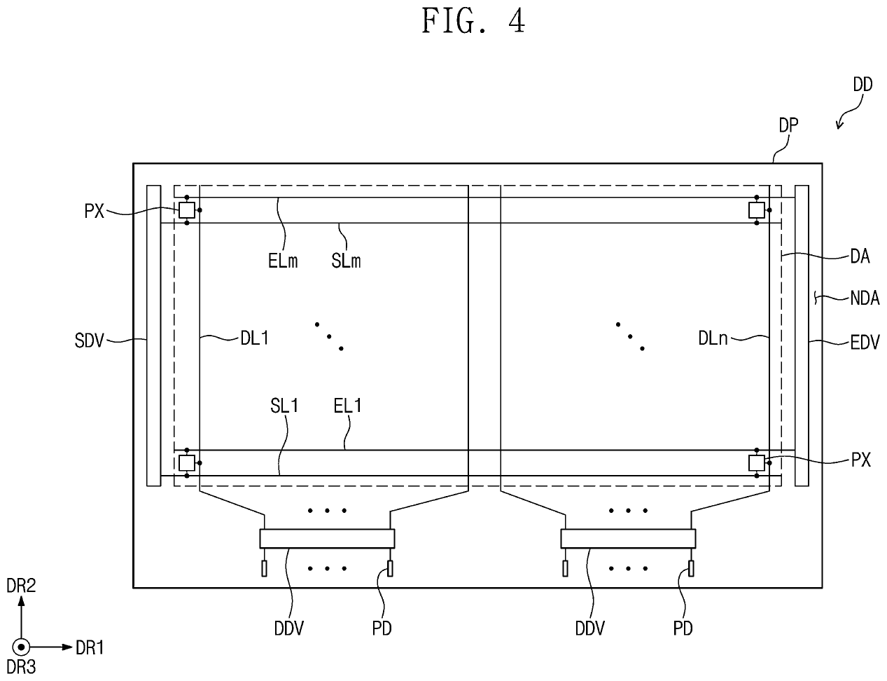

FIG. 4 is a plan view of the display panel illustrated in FIG. 3.

Referring to FIG. 4, an embodiment of the display device DD may include the display panel DP, a scan driver SDV, a plurality of data drivers DDV, a light emission driver EDV, and a plurality of pads PD.

The display panel DP may have a rectangular shape with long sides extending in the first direction DR1 and short sides extending in the second direction DR2 in a plan view. However, the shape of the display panel DP is not limited thereto. The display panel DP may include a display area DA and a non-display area NDA surrounding the display area DA.

The display panel DP may include a plurality of pixels PX, a plurality of scan lines SL1 to SLm, a plurality of data lines DL1 to DLn, and a plurality of light emission lines EL1 to ELm. Here, “m” and “n” are natural numbers.

The pixels PX may be disposed in the display area DA. The scan driver SDV and the light emission driver EDV may be disposed in the non-display areas NDA adjacent to opposite sides of the display panel DP that are opposite to each other in the first direction DR1. The data drivers DDV may be disposed in the non-display areas NDA adjacent to one of opposite sides of the display panel DP that are opposite to each other in the second direction DR2. The data drivers DDV may be adjacent to the lower end of the display panel DP when viewed from above the plane or in a plan view.

The scan lines SL1 to SLm may extend in the first direction DR1 and may be connected to the pixels PX and the scan driver SDV. The data lines DL1 to DLn may extend in the second direction DR2 and may be connected to the pixels PX and the data drivers DDV. The light emission lines EL1 to ELm may extend in the first direction DR1 and may be connected to the pixels PX and the light emission driver EDV.

The data drivers DDV may be spaced apart from each other in the first direction DR1. A certain number of data lines may be connected to each of the data drivers DDV. Although two data drivers DDV are illustrated in FIG. 4 as an example, the number of data drivers DDV is not limited thereto. In an embodiment, for example, as the left and right areas of the display panel DP are increased, the number of data drivers DDV may also be increased.

The pads PD may be disposed in the non-display area NDA adjacent to the lower end of the display panel DP and may be closer to the lower end of the display panel DP than the data drivers DDV. The data drivers DDV may be connected to the pads PD. The data lines DL1 to DLn may be connected to the data drivers DDV, and the data drivers DDV may be connected to the pads PD corresponding to the data lines DL1 to DLn.

Although not illustrated, the display device DD may further include a timing controller for controlling operations of the scan driver SDV, the data drivers DDV, and the light emission driver EDV. The timing controller may be connected to the pads PD through a printed circuit board.

The scan driver SDV may generate a plurality of scan signals, and the scan signals may be applied to the pixels PX through the scan lines SL1 to SLm. The data drivers DDV may generate a plurality of data voltages, and the data voltages may be applied to the pixels PX through the data lines DLI to DLn. The light emission driver EDV may generate a plurality of light emission signals, and the light emission signals may be applied to the pixels PX through the light emission lines EL1 to ELm.

The pixels PX may receive the data voltages in response to the scan signals. The pixels PX may display an image by emitting light having luminance corresponding to the data voltages in response to the light emission signals.

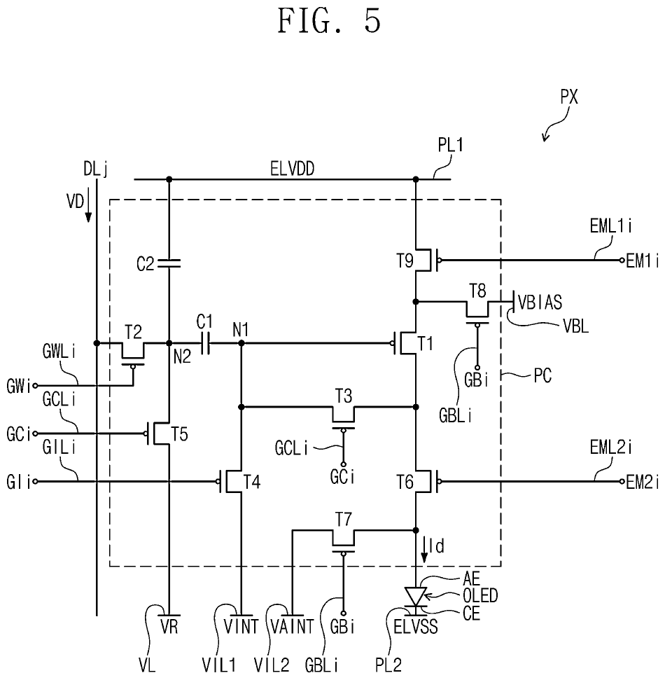

FIG. 5 is a view illustrating an equivalent circuit of one pixel illustrated in FIG. 4.

Referring to FIG. 5, an embodiment of the pixel PX may include a pixel circuit PC and a light emitting element OLED connected to the pixel circuit PC. The pixel PX illustrated in FIG. 5 may be a pixel disposed in an i-th row and a j-th column. Here, “i” and “j” are natural numbers. The row direction may correspond to the first direction DR1, and the column direction may correspond to the second direction DR2. Each of the pixels PX illustrated in FIG. 4 may have the configuration illustrated in FIG. 5.

The pixel circuit PC may drive the light emitting element OLED. The light emitting element OLED may be defined as an organic light emitting element. The light emitting element OLED may include an anode AE and a cathode CE.

The pixel circuit PC may include a plurality of transistors T1 to T9 and a plurality of capacitors C1 and C2. The transistors T1 to T9 and the capacitors C1 and C2 may control the amount of current flowing through the light emitting element OLED. The light emitting element OLED may generate light having a certain luminance depending on the amount of current provided thereto.

Among the scan lines SL1 to SLm, an i-th scan line may include an i-th write scan line GWLi, an i-th compensation scan line GCLi, an i-th initialization scan line GILi, and an i-th bias scan line GBLi.

The pixel PX may be connected to the i-th write scan line GWLi, the i-th compensation scan line GCLi, the i-th initialization scan line GILi, the i-th bias scan line GBLi, the i-th first light emission line EML1i, the i-th second light emission line EML2i, an j-th data line DLj, a first initialization (voltage) line VIL1, a second initialization (voltage) line VIL2, a reference (voltage) line VL, a bias (voltage) line VBL, and first and second power lines PL1 and PL2.

The i-th write scan line GWLi may receive an i-th write scan signal GWi, and the i-th compensation scan line GCLi may receive an i-th compensation scan signal GCi. The i-th initialization scan line GILi may receive an i-th initialization scan signal GIi, and the i-th bias scan line GBLi may receive an i-th bias scan signal GBi.

The i-th first light emission line EML1i may receive an i-th first light emission signal EM1i, and the i-th second light emission line EML2i may receive an i-th second light emission signal EM2i.

The first initialization line VIL1 may receive a first initialization voltage VINT, and the second initialization line VIL2 may receive a second initialization voltage AINT. The bias line VBL may receive a bias voltage VBIAS, and the reference line VL may receive a reference voltage VR. The first power line PL1 may receive a first voltage ELVDD, and the second power line PL2 may receive a second voltage ELVSS.

Each of the transistors T1 to T9 may include a source electrode, a drain

electrode, and a gate electrode. Hereinafter, in FIG. 5, for convenience, one of the source electrode and the drain electrode is defined as a first electrode, and the other of the source electrode and the drain electrode is defined as a second electrode. In addition, the gate electrode is defined as a control electrode.

The transistors T1 to T9 may include the first to ninth transistors T1 to T9. The first to ninth transistors T1 to T9 may be p-channel metal-oxide-semiconductor (PMOS) transistors. However, without being limited thereto, the first to ninth transistors T1 to T9 may be n-channel metal-oxide-semiconductor (NMOS) transistors. The capacitors C1 and C2 may include the first capacitor C1 and the second capacitor C2.

The transistors T1 to T9 and the capacitors C1 and C2 may be directly or indirectly connected to the above-described lines GWLi, GCLi, GILi, GBLi, EML1i, EML2i, DLj, VIL1, VIL2, VL, VBL, PL1, and PL2 and the light emitting element OLED.

In an embodiment, for example, the second transistor T2 may be directly connected to the j-th data line DLj and the i-th write scan line GWLi, and the first capacitor C1 may be indirectly connected to the j-th data line DLj through the second transistor T2. The eighth transistor T8 may be directly connected to the bias line VBL, and the first transistor T1 may be indirectly connected to the bias line VBL through the eighth transistor T8. The sixth transistor T6 may be directly connected to the light emitting element OLED, and the first transistor T1 may be indirectly connected to the light emitting element OLED through the sixth transistor T6.

The first transistor T1 may be connected to the light emitting element OLED and the first power line PL1 and may be switched by a voltage of a first node N1. In an embodiment, for example, the first transistor T1 may be connected to the anode AE of the light emitting element OLED through the sixth transistor T6 and may be connected to the first power line PL1 through the ninth transistor T9. The first transistor T1 may be disposed between the sixth transistor T6 and the ninth transistor T9 and may be connected to the sixth transistor T6 and the ninth transistor T9.

The first transistor T1 may include a first electrode connected to the ninth transistor T9, a second electrode connected to the sixth transistor T6, and a control electrode connected to the first node N1. The first transistor T1 may control the amount of current flowing through the light emitting element OLED depending on the voltage of the first node N1 applied to the control electrode of the first transistor T1. The first transistor T1 may be defined as a driving transistor.

The second transistor T2 may be disposed between the j-th data line DLj and a second node N2 and may be connected to the j-th data line DLj and the second node N2. The second transistor T2 may be switched by the i-th write scan signal GWi. The second transistor T2 may include a first electrode connected to the j-th data line DLj, a second electrode connected to the second node N2, and a control electrode connected to the i-th write scan line GWLi. The second transistor T2 may be defined as a switching transistor.

The first capacitor C1 may be connected to the first node N1 and the second node N2. The first capacitor C1 may be connected to the control electrode of the first transistor T1 through the first node N1 and may be connected to the second electrode of the second transistor T2 through the second node N2. The first capacitor C1 may include a first electrode connected to the first node N1 and a second electrode connected to the second node N2.

The second transistor T2 may be turned on by the i-th write scan signal GWi applied through the i-th write scan line GWLi. The turned-on second transistor T2 may receive a data voltage VD through the j-th data line DLj. The data voltage VD may be provided to the first capacitor C1 through the turned-on second transistor T2. The third transistor T3 may be connected to the second electrode of the

first transistor T1 and the first node N1. The third transistor T3 may include a first electrode connected to the second electrode of the first transistor T1, a second electrode connected to the first node N1, and a control electrode connected to the i-th compensation scan line GCLi.

The third transistor T3 may be turned on by the i-th compensation scan signal GCi applied through the i-th compensation scan line GCLi and may connect the second electrode of the first transistor T1 and the control electrode of the first transistor T1. When the third transistor T3 is turned on, the first transistor T1 and the third transistor T3 may be connected to each other in the form of a diode. The third transistor T3 may be defined as a compensation transistor.

The fourth transistor T4 may be connected to the first node N1. The fourth transistor T4 may include a first electrode connected to the first node N1, a second electrode connected to the first initialization line VIL1, and a control electrode connected to the i-th initialization scan line GILi.

The fourth transistor T4 may be turned on by the i-th initialization scan signal GIi applied through the i-th initialization scan line GILi. The turned-on fourth transistor T4 may provide the first initialization voltage VINT applied through the first initialization line VIL1 to the first node N1. The fourth transistor T4 may be defined as a first initialization transistor.

The fifth transistor T5 may be disposed between the reference line VL and the second node N2 and may be connected to the reference line VL and the second node N2. The fifth transistor T5 may be switched by the i-th compensation scan signal GCi.

The fifth transistor T5 may include a first electrode connected to the second node N2, a second electrode connected to the reference line VL, and a control electrode connected to the i-th compensation scan line GCLi. The fifth transistor T5 may be turned on by the i-th compensation scan signal GCi applied through the i-th compensation scan line GCLi. The turned-on fifth transistor T5 may provide the reference voltage VR applied through the reference line VL to the second node N2. The fifth transistor T5 may be defined as a reference transistor.

The sixth transistor T6 may be connected to the first transistor T1 and the anode AE and may be switched by the i-th second light emission signal EM2i. The sixth transistor T6 may include a first electrode connected to the second electrode of the first transistor T1, a second electrode connected to the anode AE, and a control electrode connected to the i-th second light emission line EML2i.

The sixth transistor T6 may be turned on by the i-th second light emission signal EM2i applied through the i-th second light emission line EML2i. The sixth transistor T6 may be defined as a first light emission control transistor.

The seventh transistor T7 may be connected to the anode AE and the second initialization line VIL2 and may be switched by the i-th bias scan signal GBi. The seventh transistor T7 may include a first electrode connected to the anode AE, a second electrode connected to the second initialization line VIL2, and a control electrode connected to the i-th bias scan line GBLi.

The seventh transistor T7 may be turned on by the i-th bias scan signal GBi applied through the i-th bias scan line GBLi. The turned-on seventh transistor T7 may provide the second initialization voltage VAINT received through the second initialization line VIL2 to the anode AE of the light emitting element OLED. The seventh transistor T7 may be defined as a second initialization transistor.

The eighth transistor T8 may be connected to the first transistor T1 and the bias line VBL and may be switched by the i-th bias scan signal GBi. The eighth transistor T8 may include a first electrode connected to the bias line VBL, a second electrode connected to the first electrode of the first transistor T1, and a control electrode connected to the i-th bias scan line GBLi.

The eighth transistor T8 may be turned on by the i-th bias scan signal GBi applied through the i-th bias scan line GBLi. The turned-on eighth transistor T8 may provide the bias voltage VBIAS received through the bias line VBL to the first electrode of the first transistor T1. The eighth transistor T8 may be defined as a bias transistor.

The ninth transistor T9 may be connected to the first power line PL1 and the first transistor T1 and may be switched by the i-th first light emission signal EM1i. The ninth transistor T9 may include a first electrode connected to the first power line PL1, a second electrode connected to the first electrode of the first transistor T1, and a control electrode connected to the i-th first light emission line EML1i.

The ninth transistor T9 may be turned on by the i-th first light emission signal EM1i applied through the i-th first light emission line EML1i. The ninth transistor T9 may be defined as a second light emission control transistor. When the sixth and ninth transistors T6 and T9 are turned on, the first voltage ELVDD may be provided to the light emitting element OLED, and a driving current ID may flow through the light emitting element OLED. Accordingly, the light emitting element OLED may emit light.

The second capacitor C2 may include a first electrode connected to the second node N2 and a second electrode connected to the first power line PL1.

The light emitting element OLED may be connected to the corresponding sixth transistor T6 among the transistors T1 to T9. The anode AE of the light emitting element OLED may be connected to the first power line PL1 through the sixth, first, and ninth transistors T6, T1, and T9. The anode AE of the light emitting element OLED may receive the first voltage ELVDD through the sixth, first, and ninth transistors T6, T1, and T9.

The cathode CE of the light emitting element OLED may be connected to the second power line PL2. The cathode CE of the light emitting element OLED may receive the second voltage ELVSS having a lower level than the first voltage ELVDD through the second power line PL2.

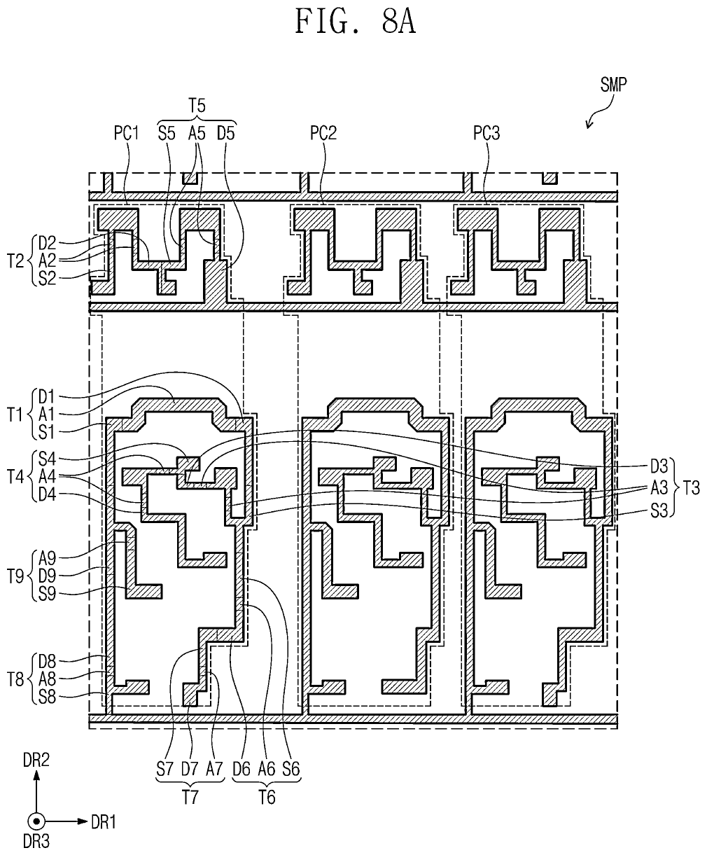

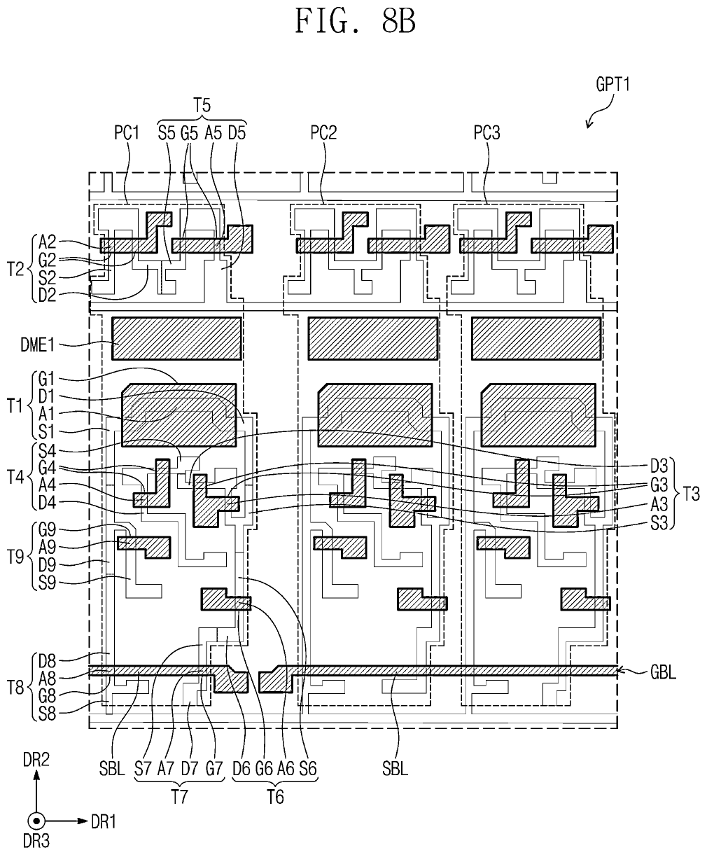

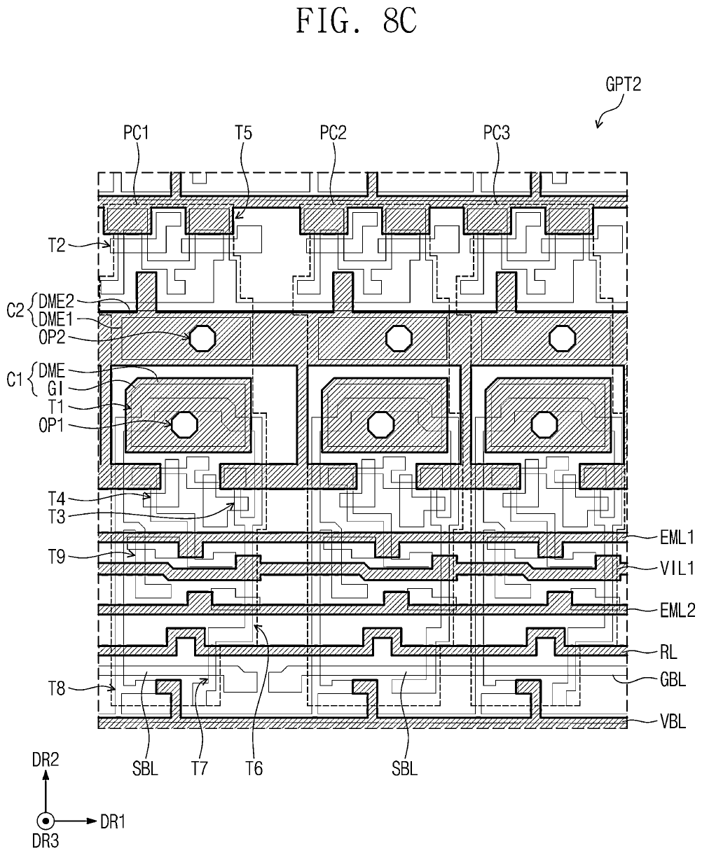

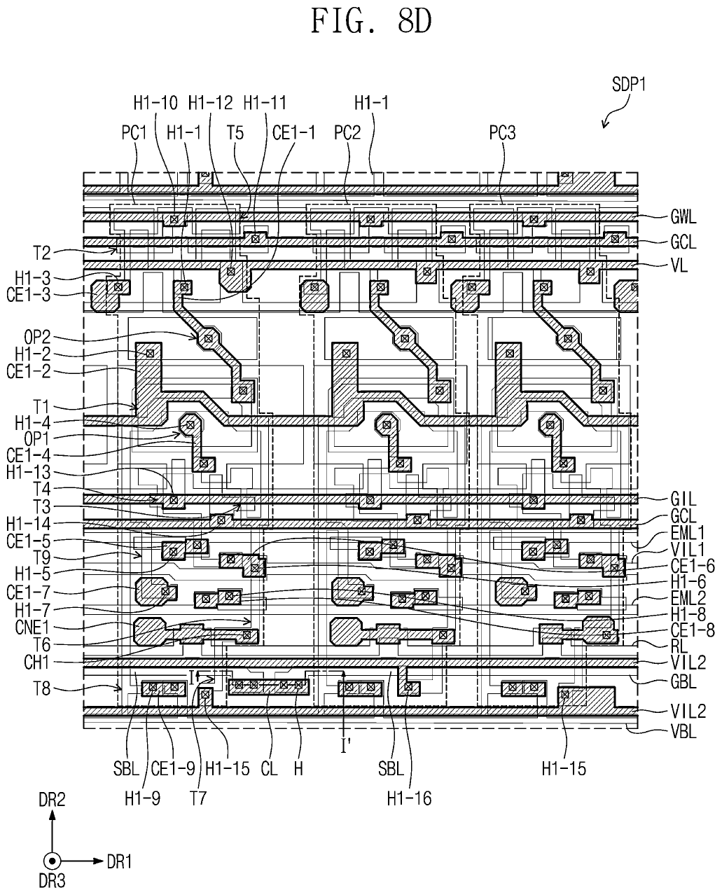

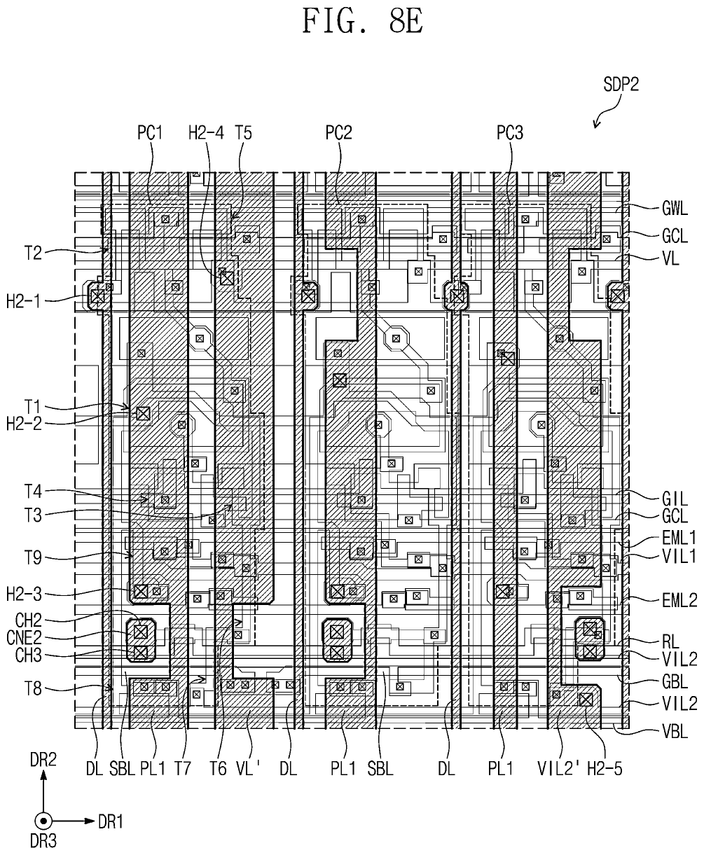

The pixel PX may substantially include three pixel circuits PC and three light emitting elements OLED connected to the three pixel circuits PC, respectively. The three pixel circuits PC will be illustrated in the layout diagrams of FIGS. 8A to 8E.

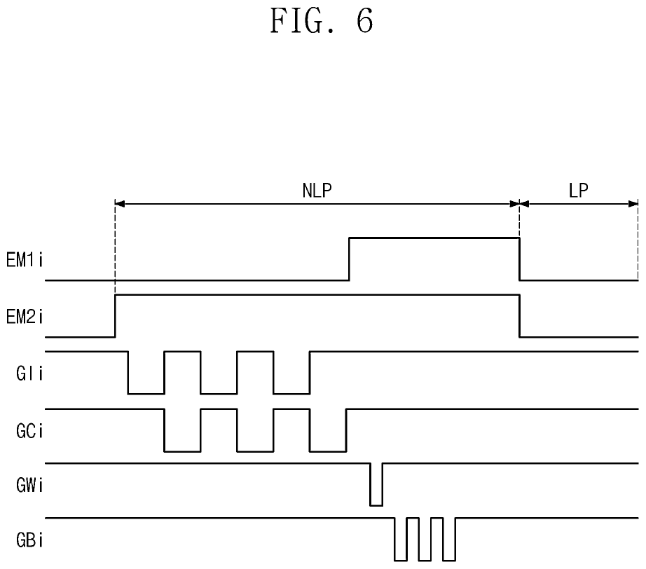

FIG. 6 is a signal timing diagram of signals for driving the pixel illustrated in FIG. 5.

Hereinafter, an activation period of each signal represents a low level in the timing chart of FIG. 6, and a deactivation period of each signal represents a high level in the timing chart of FIG. 6.

Referring to FIGS. 5 and 6, the i-th first light emission signal EM1i may be activated and deactivated during a non-light emission period NLP. The i-th first light emission signal EM1i may be activated during a light emission period LP. The i-th second light emission signal EM2i may be deactivated during the non-light emission period NLP in one frame period and may be activated during the light emission period LP in the one frame period.

In the non-light emission period NLP, the i-th initialization scan signal GIi and the i-th compensation scan signal GCi may be repeatedly activated during the activation period of the i-th first light emission signal EM1i. The i-th initialization scan signal GIi may be activated first, and then the i-th compensation scan signal GCi may be activated. The activation period of the i-th initialization scan signal GIi may not overlap the activation period of the i-th compensation scan signal GCi.

In the non-light emission period NLP, the i-th initialization scan signal GIi and the i-th compensation scan signal GCi may be deactivated during the deactivation period of the i-th first light emission signal EM1i. In the deactivation period of the i-th first light emission signal EM1i, the i-th write scan signal GWi may be activated, and thereafter the i-th bias scan signal GBi may be activated. The i-th bias scan signal GBi may be repeatedly activated during the deactivation period of the i-th first light emission signal EM1i.

In an embodiment, for example, the i-th initialization scan signal GIi, the i-th compensation scan signal GCi, and the i-th bias scan signal GBi may each be activated three times during the non-light emission period NLP. However, the number of activations during the non-light emission period NLP is not limited thereto. In the light emission period LP, the i-th initialization scan signal GIi, the i-th compensation scan signal GCi, the i-th write scan signal GWi, and the i-th bias scan signal GBi may be deactivated.

In the non-light emission period NLP, the ninth transistor T9 may be turned on by the activated i-th first light emission signal EM1i, and the first voltage ELVDD may be applied to the first electrode (or the source) of the first transistor T1.

In the non-light emission period NLP, the fourth transistor T4 may be turned on by the activated i-th initialization scan signal GIi. The first initialization voltage VINT may be provided to the first node N1 through the fourth transistor T4, and the first transistor T1 may be initialized. This operation may be defined as an initialization operation.

Thereafter, in the non-light emission period NLP, the activated i-th compensation scan signal GCi may be applied to the third transistor T3, and the third transistor T3 may be turned on. The first transistor T1 and the third transistor T3 may be turned on and may be connected in the form of a diode. In this case, a compensation voltage (ELVDD-Vth) obtained by subtracting the threshold voltage (Vth) of the first transistor T1 from the first voltage ELVDD may be applied to the control electrode of the first transistor T1. This operation may be defined as a threshold voltage compensation operation.

In the non-light emission period NLP, the activated i-th compensation scan signal GCi may be applied to the fifth transistor T5, and the fifth transistor T5 may be turned on. The reference voltage VR may be applied to the second node N2 by the turned-on fifth transistor T5.

The above-described initialization and compensation operations may be repeatedly performed while the i-th initialization scan signal GIi and the i-th compensation scan signal GCi are repeatedly activated. As the initialization operation is repeatedly performed, data written to the first node N1 in the previous frame may be more effectively or completely removed, and the first transistor T1 may be more effectively or completely initialized.

A parasitic capacitor may exist in the third and fourth transistors T3 and T4. The gate-source voltages of the third and fourth transistors T3 and T4 may be varied by the parasitic capacitor. The second capacitor C2 may have a larger capacity than the parasitic capacitor. The second capacitor C2 having a larger capacity than the parasitic capacitor may be connected to the third and fourth transistors T3 and T4 through the first node N1. The second capacitor C2 having a larger capacity than the parasitic capacitor may suppress the variation of the gate-source voltage levels of the third and fourth transistors T3 and T4.

Thereafter, in the non-light emission period NLP, the activated i-th write scan signal GWi may be applied to the second transistor T2, and the second transistor T2 may be turned on. The data voltage VD may be provided to the first capacitor C1 through the second transistor T2. In this case, the data voltage VD may be applied to the second node N2, and the voltage of the first node N1 may be ELVDD-Vth+VD-VR.

The seventh and eighth transistors T7 and T8 may be turned on by the activated i-th bias scan signal GBi. The second initialization voltage VAINT may be provided to the anode AE through the seventh transistor T7, and the bias voltage VBIAS may be applied to the first electrode of the first transistor T1 through the eighth transistor T8.

During the non-light emission period LP, the activated i-th first and second light emission signals EM1i and EM2i may be applied to the ninth transistor T9 and the sixth transistor T6, and the ninth transistor T9 and the sixth transistor T6 may be turned on. The driving current Id may be provided to the light emitting element OLED through the sixth transistor T6, and the light emitting element OLED may emit light.

The source-gate voltage (Vsg) of the first transistor T1 may be defined as a voltage difference between the first voltage ELVDD and the voltage ELVDD-Vth+VD-VR of the first node N1. When the source-gate voltage (Vsg) of the first transistor T1 is substituted into Equation 1 below, the threshold voltage (Vth) may be removed, and the driving current (Id) of Equation 1 may be proportional to (VR-VD)², which is the square of the value obtained by subtracting the data voltage VD from the reference voltage VR. Accordingly, the driving current (Id) may be determined irrespective of the threshold voltage (Vth) of the first transistor T1.

Id=(½)μCox(W/L)(Vsg−Vth)² (1)

Equation 1 expresses a current-voltage relationship for a general transistor.

The bias voltage VBIAS may be applied to the first electrode of the first transistor T1 through the eighth transistor T8 before the light emitting element OLED emits light after the threshold voltage of the first transistor T1 is compensated for. Movement of the hysteresis curve of the first transistor T1 may be suppressed by the bias voltage VBIAS. This operation may be defined as a bias operation.

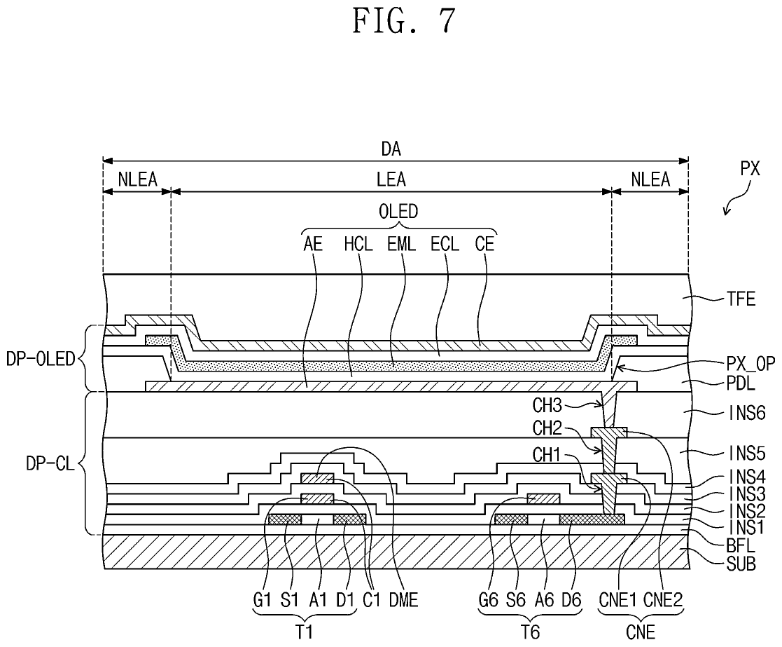

FIG. 7 is a sectional view illustrating the light emitting element, the first transistor, and the sixth transistor of the pixel illustrated in FIG. 5.

Referring to FIG. 7, in an embodiment, the light emitting element OLED may include a first electrode AE, a second electrode CE, a hole control layer HCL, an electron control layer ECL, and an emissive layer EML. The first electrode AE may be the anode AE illustrated in FIG. 5, and the second electrode CE may be the cathode CE illustrated in FIG. 5. The second electrode CE may be disposed over the first electrode AE, and the hole control layer HCL, the electron control layer ECL, and the emissive layer EML may be disposed between the first electrode AE and the second electrode CE.

The first and sixth transistors T1 and T6 and the light emitting element OLED may be disposed on the substrate SUB. The display area DA may include an emissive area LEA corresponding to the pixel PX and a non-emissive area NLEA adjacent to or surrounding the emissive area LEA. The light emitting element OLED may be disposed in the emissive area LEA in a plan view.

A buffer layer BFL may be disposed on the substrate SUB. The buffer layer BFL may be an inorganic layer. A semiconductor layer S1, A1, and D1 of the first transistor T1 and a semiconductor layer S6, A6, and D6 of the sixth transistor T6 may be disposed on the buffer layer BFL. In an embodiment, the semiconductor layers S1, A1, D1, S6, A6, and D6 may include poly silicon. Alternatively, without being limited thereto, the semiconductor layers S1, A1, D1, S6, A6, and D6 may include amorphous silicon.

The semiconductor layers S1, A1, D1, S6, A6, and D6 may be doped with an N-type dopant or a P-type dopant. The semiconductor layers S1, A1, D1, S6, A6, and D6 may include highly doped areas and lightly doped areas. The highly doped areas (e.g., source areas and drain areas) may have higher conductivity than the lightly doped areas and may substantially serve as the source electrodes and the drain electrodes of the first and sixth transistors T1 and T6. The lightly doped areas may substantially correspond to channel areas (or channels) of the first and sixth transistors T1 and T6.

The semiconductor layer S1, A1, and D1 of the first transistor T1 may include the first source area S1, the first channel area A1, and the first drain area D1. The semiconductor layer S6, A6, and D6 of the sixth transistor T6 may include the sixth source area S6, the sixth channel area A6, and the sixth drain area D6. The first channel area Al may be disposed between the first source area S1 and the first drain area D1. The sixth channel area A6 may be disposed between the sixth source area S6 and the sixth drain area D6.

A first insulating layer INS1 may be disposed on the buffer layer BFL to cover the semiconductor layers S1, A1, D1, S6, A6, and D6. The first and sixth gate electrodes G1 and G6 (or the control electrodes) of the first and sixth transistors T1 and T6 may be disposed on the first insulating layer INS1.

The first gate electrode G1 may be disposed over the semiconductor layer S1, A1, and D1, and the sixth gate electrode G6 may be disposed over the semiconductor layer S6, A6, and D6. The first gate electrode G1 may be disposed over the first channel area A1 and may overlap the first channel area A1. The sixth gate electrode G6 may be disposed over the sixth channel area A6 and may overlap the sixth channel area A6.

Although not illustrated, the other transistors T2 to T5 and T7 to T9 may also have substantially the same configuration as the first and sixth transistors T1 and T6.

A second insulating layer INS2 may be disposed on the first insulating layer INS1 to cover the first and sixth gate electrodes G1 and G6. A dummy electrode DME may be disposed on the second insulating layer INS2. The dummy electrode DME may be disposed over the first gate electrode G1 and may overlap the first gate electrode G1 when viewed from above the plane or in a plan view (i.e., when viewed in a thickness direction of the substrate SUB).

The dummy electrode DME may form the above-described first capacitor C1 together with the first gate electrode G1. The first gate electrode G1 may define the first electrode of the first capacitor C1, and the dummy electrode DME may define the second electrode of the first capacitor C1.

A third insulating layer INS3 may be disposed on the second insulating layer INS2 to cover the dummy electrode DME. A fourth insulating layer INS4 may be disposed on the third insulating layer INS3. The buffer layer BFL and the first to fourth insulating layers INS1 to INS4 may include inorganic layers.

A connecting electrode CNE may be disposed between the sixth transistor T6 and the light emitting element OLED. The connecting electrode CNE may electrically connect the sixth transistor T6 and the light emitting element OLED. The connecting electrode CNE may include a first connecting electrode CNE1 and a second connecting electrode CNE2 disposed over the first connecting electrode CNE1.

The first connecting electrode CNE1 may be disposed on the third insulating layer INS3, and the fourth insulating layer INS4 may be disposed on the first connecting electrode CNE1. The first connecting electrode CNE1 may be disposed above the dummy electrode DME and may be connected to the corresponding sixth transistor T6. The first connecting electrode CNE1 may be connected to the sixth drain area D6 through a first contact hole CH1 defined in the first to third insulating layers INS1 to INS3.

A fifth insulating layer INS5 may be disposed on the fourth insulating layer INS4. The second connecting electrode CNE2 may be disposed on the fifth insulating layer INS5. The second connecting electrode CNE2 may be connected to the first connecting electrode CNE1 through a second contact hole CH2 defined in the fourth and fifth insulating layers INS4 and INS5. A sixth insulating layer INS6 may be disposed on the fifth insulating layer INS5 to cover the second connecting electrode CNE2. The fifth and sixth insulating layers INS5 and INS6 may include an inorganic layer or an organic layer.

The light emitting element OLED may be disposed on the sixth insulating layer INS6. The light emitting element OLED may be disposed on the second connecting electrode CNE2 and may be connected to the second connecting electrode CNE2. In an embodiment, the first electrode AE may be disposed on the sixth insulating layer INS6. The first electrode AE may be connected to the second connecting electrode CNE2 through a third contact hole CH3 defined in the sixth insulating layer INS6.

A pixel defining layer PDL exposing a certain portion of the first electrode AE may be disposed on the first electrode AE and the sixth insulating layer INS6. An opening PX-OP for exposing the certain portion of the first electrode AE may be defined in the pixel defining layer PDL.

The hole control layer HCL may be disposed on the first electrode AE and the pixel defining layer PDL. The hole control layer HCL may be commonly disposed in the emissive area LEA and the non-emissive area NLEA. The hole control layer HCL may include a hole transport layer and a hole injection layer.

The emissive layer EML may be disposed on the hole control layer HCL. The emissive layer EML may be disposed in an area corresponding to the opening PX_OP. The emissive layer EML may include an organic material and/or an inorganic material. The emissive layer EML may generate one of red light, green light, and blue light.

The electron control layer ECL may be disposed on the emissive layer EML and the hole control layer HCL. The electron control layer ECL may be commonly disposed in the emissive area LEA and the non-emissive area NLEA. The electron control layer ECL may include an electron transport layer and an electron injection layer.

The second electrode CE may be disposed on the electron control layer ECL. The second electrode CE may be commonly disposed for the pixels PX. That is, the second electrode CE may be commonly disposed over the emissive layers EML of the pixels PX.

The layers from the buffer layer BFL to the sixth insulating layer INS6 may be defined as the circuit element layer DP-CL. The layer in which the light emitting element OLED is disposed may be defined as the display element layer DP-OLED.

The thin film encapsulation layer TFE may be disposed on the light emitting element OLED. The thin film encapsulation layer TFE may include an inorganic layer, an organic layer, and an in organic layer that are sequentially stacked one above another. The inorganic layers may include an inorganic material and may protect the pixels from moisture/oxygen. The organic layer may include an organic material and may protect the pixels PX from foreign matter such as dust particles.

The first voltage ELVDD may be applied to the first electrode AE, and the second voltage EVLSS may be applied to the second electrode CE. Holes and electrons injected into the emissive layer EML may be combined to form excitons, and the light emitting element OLED may emit light as the excitons transition to a ground state. An image may be displayed as the light emitting element OLED emits the light.

FIGS. 8A to 8E are views illustrating a planar structure of the pixel illustrated in FIG. 5 in a layer-by-layer manner.

The plan views illustrated in FIGS. 8A to 8E may be substantially plan views of layers defining the first to ninth transistors T1 to T9 and the first and second capacitors C1 and C2. The views illustrated in FIGS. 8A to 8E may be defined as layout diagrams. In the description of FIGS. 8A to 8E, the term “overlap” indicates a state in which components overlap each other when viewed from above the plane or in a plan view, that is, when viewed in the third direction DR3.

Referring to FIGS. 8A to 8E, each of first, second, and third pixel circuits PC1, PC2, and PC3 may correspond to the pixel circuit PC illustrated in FIG. 5. Each of the first, second, and third pixel circuits PC1, PC2, and PC3 may be connected to the light emitting element OLED illustrated in FIGS. 5 and 7.

The first, second, and third pixel circuits PC1, PC2, and PC3 may be arranged in the first direction DR1. The gap between the first pixel circuit PC1 and the second pixel circuit PC2 in the first direction DR1 may be greater than the gap between the second pixel circuit PC2 and the third pixel circuit PC3 in the first direction DR1. Accordingly, the first pixel circuit PC1 and the second pixel circuit PC2 may be spaced further apart from each other than the second pixel circuit PC2 and the third pixel circuit PC3 are.

The above-described pixel PX may include a first sub-pixel, a second sub-pixel, and a third sub-pixel. The first sub-pixel may include the first pixel circuit PC1 and a light emitting element OLED connected to the first pixel circuit PC1. The second sub-pixel may include the second pixel circuit PC2 and a light emitting element OLED connected to the second pixel circuit PC2. The third sub-pixel may include the third pixel circuit PC3 and a light emitting element OLED connected to the third pixel circuit PC3.

In an embodiment, for example, the first sub-pixel may display red, the second sub-pixel may display green, and the third sub-pixel may display blue. The first, second, and third pixel circuits PC1, PC2, and PC3 have substantially the same configuration as each other, and therefore the configuration of the first pixel circuit PC1 will hereinafter be mainly described.

In FIGS. 8A to 8E, the boundaries between the first, second, and third pixel circuits PC1, PC2, and PC3 are illustrated by dotted lines. Each of the first, second, and third pixel circuits PC1, PC2, and PC3 may be defined as an area where the first to ninth transistors T1 to T9 and the first and second capacitors C1 and C2 are formed.

Referring to FIG. 8A, a semiconductor pattern SMP illustrated in FIG. 8A may be disposed on the above-described substrate SUB. The semiconductor pattern SMP may have various shapes without being limited to the shape illustrated in FIG. 8A. The semiconductor pattern SMP may include first to ninth sources areas S1 to S9, first to ninth drain areas D1 to D9, and first to ninth channel areas A1 to A9.

The first semiconductor layer S1, A1, and D1 of the first transistor T1, the second semiconductor layer S2, A2, and D2 of the second transistor T2, the third semiconductor layer S3, A3, and D3 of the third transistor T3, the fourth semiconductor layer S4, A4, and D4 of the fourth transistor T4, the fifth semiconductor layer S5, A5, and D5 of the fifth transistor T5, the sixth semiconductor layer S6, A6, and D6 of the sixth transistor T6, the seventh semiconductor layer S7, A7, and D7 of the seventh transistor T7, the eighth semiconductor layer S8, A8, and D8 of the eighth transistor T8, and the ninth semiconductor layer S9, A9, and D9 of the ninth transistor T9 may be defined or formed by the semiconductor pattern SMP.

The first to ninth channel areas A1 to A9 may be disposed between the first to ninth source areas S1 to S9 and the first to ninth drain areas D1 to D9. In an embodiment, the second, third, fourth, and fifth transistors T2, T3, T4, and T5 may have a dual gate structure. Each of the second, third, fourth, and fifth channel areas A2, A3, A4, and A5 of the second, third, fourth, and fifth transistors T2, T3, T4, and T5 having the dual gate structure may be formed of two channel areas.

The second and fifth semiconductor layers S2, A2, D2, S5, A5, and D5 may be spaced apart or disconnected from the first, third, fourth, sixth, seventh, eighth, and ninth semiconductor layers S1, A1, D1, S3, A3, D3, S4, A4, D4, S6, A6, D6, S7, A7, D7, S8, A8, D8, S9, A9, and D9.

The second drain area D2 of the second transistor T2 may extend from the fifth source area S5 of the fifth transistor T5. The third source area S3 of the third transistor T3 may extend from the first drain area D1 of the first transistor T1. The sixth source area S6 of the sixth transistor T6 may extend from the third source area S3 of the third transistor T3.

The fourth source area S4 of the fourth transistor T4 may extend from the third drain area D3 of the third transistor T3. The seventh source area S7 of the seventh transistor T7 may extend from the sixth drain area D6 of the sixth transistor T6.

The ninth drain area D9 of the ninth transistor T9 may extend from the first source area S1 of the first transistor T1. The eighth drain area D8 of the eighth transistor T8 may extend from the ninth drain area D9 of the ninth transistor T9.

Hereinafter, for convenience of description, the names and symbols “i-th” and “j-th” are omitted when the lines illustrated in FIGS. 8B to 8E are referred to.

Referring to FIGS. 8A and 8B, a first gate pattern GPT1 may be disposed on the semiconductor pattern SMP. The first gate pattern GPT1 may include the first, second, third, fourth, fifth, sixth, and ninth gate electrodes G1, G2, G3, G4, G5, G6, and G9, a bias scan line GBL, and a first dummy electrode DME1.

The first gate electrode G1 of the first transistor T1, the second gate electrode G2 of the second transistor T2, the third gate electrode G3 of the third transistor T3, the fourth gate electrode G4 of the fourth transistor T4, the fifth gate electrode G5 of the fifth transistor T5, the sixth gate electrode G6 of the sixth transistor T6, and the ninth gate electrode G9 of the ninth transistor T9 may be defined or formed by the first gate pattern GPT1.

The first gate electrode G1 may overlap the first channel area A1, the second gate electrode G2 may overlap the second channel area A2, the third gate electrode G3 may overlap the third channel area A3, the fourth gate electrode G4 may overlap the fourth channel area A4, the fifth gate electrode G5 may overlap the fifth channel area A5, the sixth gate electrode G6 may overlap the sixth channel area A6, and the ninth gate electrode G9 may overlap the ninth channel area A9.

In an embodiment, each of the second, third, fourth, and fifth gate electrodes G2, G3, G4, and G5 of the second, third, fourth, and fifth transistors T2, T3, T4, and T5 having the dual gate structure may be formed of two gate electrodes.

The bias scan line GBL may extend in the first direction DR1. The bias scan line GBL may be adjacent to the lower side of the first pixel circuit PC1. The bias scan line GBL may be divided into tow portions extending in the first direction DR1 to form sub-bias scan lines SBL. Accordingly, the bias scan line GBL may include two sub-bias scan lines SBL spaced apart from each other in the first direction DR1. The sub-bias scan lines SBL may be spaced apart from each other at an area or region between the first pixel circuit PC1 and the second pixel circuit PC2, that is, end portions of the sub-bias scan lines SBL facing and spaced apart from each other in the first direction are disposed in the area between the first pixel circuit PC1 and the second pixel circuit PC2.

The bias scan line GB may extend to cross the semiconductor pattern SMP. The seventh and eighth gate electrodes G7 and G8 of the seventh and eighth transistors T7 and T8 may be formed by the bias scan line GBL. Portions of the bias scan line GBL that overlap the semiconductor pattern SMP may be defined as the seventh and eighth gate electrodes G7 and G8. The seventh gate electrode G7 may overlap the seventh channel area A7, and the eighth gate electrode G8 may overlap the eighth channel area A8.

The first dummy electrode DME1 may be disposed between the first transistor T1 and the second and fifth transistors T2 and T5. The first dummy electrode DME1 may extend longer in the first direction DR1 than in the second direction DR2, that is, a length of the first dummy electrode DME1 in the first direction DR1 may extend longer than a length of the first dummy electrode DME1 in the second direction DR2.

In FIGS. 8C to 8E, for convenience of description and illustration, the reference numerals of the source areas S1 to S9, the drain areas D1 to D9, the channel areas A1 to A9, and the gate electrodes G1 to G9 of the first to ninth transistors T1 to T9 are omitted, and the reference numerals of the first to ninth transistors T1 to T9 are illustrated. However, for convenience of description, the reference numeral of the first gate electrode G1 is illustrated only in FIG. 8C.

In FIGS. 8C to 8E, the omitted reference numerals of the source areas S1 to S9, the drain areas D1 to D9, the channel areas A1 to A9, and the gate electrodes G1 to G9 are referred to those shown in FIGS. 8A and 8B.

Referring to FIGS. 8A to 8C, a second gate pattern GPT2 may be disposed on the first gate pattern GPT1. The second gate pattern GPT2 may include the dummy electrode DME, a second dummy electrode DME2, a first light emission line EML1, the first initialization line VIL1, a second light emission line EML2, a repair line RL, and the bias line VBL.

The dummy electrode DME may overlap the first gate electrode G1. The dummy electrode DME may form the first capacitor C1 together with the first gate electrode G1. A first opening OP1 may be defined in the dummy electrode DME. A portion of the first gate electrode G1 may be exposed by the first opening OP1.

The second dummy electrode DME2 may overlap the first dummy electrode DME1. The second dummy electrode DME2 may form the second capacitor C2 together with the first dummy electrode DME1. A second opening OP2 may be defined in the second dummy electrode DME2. A portion of the first dummy electrode DME1 may be exposed by the second opening OP2.

The second dummy electrode DME2 may extend toward the third transistor T3 and the fourth transistor T4. The second dummy electrode DME2 may overlap a portion of the semiconductor pattern SMP between the third channel areas A3 and a portion of the semiconductor pattern SMP between the fourth channel areas A4.

The dummy electrode DME and the second dummy electrode DME2 may be adjacent to each other in the second direction DR2. The dummy electrode DME and the second dummy electrode DME2 may be closer to the upper side of the first pixel circuit PC1 than the first light emission line EML1, the first initialization line VIL1, the second light emission line EML2, the repair line RL, and the bias line VBL.

The first light emission line EML1, the first initialization line VIL1, the second light emission line EML2, the repair line RL, and the bias line VBL may extend in the first direction DR1 and may be arranged in the second direction DR2. The first light emission line EML1, the first initialization line VIL1, the second light emission line EML2, the repair line RL, and the bias line VBL may be closer to the lower side of the first pixel circuit PC1 than the dummy electrode DME and the second dummy electrode DME2.

The first light emission line EML1, the first initialization line VIL1, the second light emission line EML2, and the repair line RL may be disposed between the dummy electrode DME and the bias line VBL. The first light emission line EML1 may be disposed between the dummy electrode DME and the first initialization line VIL1. The first initialization line VIL1 may be disposed between the first light emission line EML1 and the second light emission line EML2.

The second light emission line EML2 may be disposed between the first initialization line VIL1 and the repair line RL. The bias scan line GBL may be disposed between the repair line RL and the bias line VBL. The bias line VBL may be closer to the lower side of the first pixel circuit PC1 than the bias scan line GBL.

In FIGS. 8D and 8E, the reference numerals of the first and second capacitors C1 and C2, the dummy electrode DME, and the first and second dummy electrodes DME1 and DME2 are omitted, and the omitted reference numerals of the first and second capacitors C1 and C2, the dummy electrode DME, and the first and second dummy electrodes DME1 and DME2 are referred to those shown in FIG. 8C.

Referring to FIGS. 8A to 8D, a first connecting pattern SDP1 may be disposed on the second gate pattern GPT2. The first connecting pattern SDP1 may be defined as a first source-drain pattern.

The first connecting pattern SDP1 may include a plurality of first connecting electrodes CNE1 and CE1-1 to CE1-9, a connecting line CL, a write scan line GWL, compensation scan lines GCL, the reference line VL, an initialization scan line GIL, and the second initialization lines VIL2. The first connecting electrode CNE1 may be the first connecting electrode CEN1 illustrated in FIG. 7. The write scan line GWL, the compensation scan lines GCL, the reference line VL, the initialization scan line GIL, and the second initialization lines VIL2 may extend in the first direction DR1 and may be arranged in the second direction DR2.

The write scan line GWL, one compensation scan line GCL, and the reference line VL may be adjacent to the upper side of the first pixel circuit PC1. The one compensation scan line GCL may be disposed between the write scan line GWL and the reference line VL. The write scan line GWL may be closer to the upper side of the first pixel circuit PC1 than the one compensation scan line GCL.

The initialization scan line GIL, another compensation scan line GCL, and the second initialization lines VIL2 may be closer to the lower side of the first pixel circuit PC1 than the write scan line GWL, the one compensation scan line GCL, and the reference line VL.

The initialization scan line GIL may be adjacent to the dummy electrode DME. The other compensation scan line GCL may be disposed between the initialization scan line GIL and the first light emission line EML1. One second initialization line VIL2 may be disposed between the repair line RL and the bias scan line GBL. Another second initialization line VIL2 may be disposed between the bias scan line GBL and the bias line VBL.

The first connecting electrodes CE1-1 to CE1-9, the connecting line CL, the write scan line GWL, the compensation scan lines GCL, the reference line VL, the initialization scan line GIL, and the second initialization lines VIL2 may be disposed in (or directly on) a same layer as the first connecting electrode CNE1. The first connecting electrodes CE1-1 to CE1-9, the connecting line CL, the write scan line GWL, the compensation scan lines GCL, the reference line VL, the initialization scan line GIL, and the second initialization lines VIL2 may be simultaneously subjected to patterning with the same material as that of the first connecting electrode CNE1.

A plurality of contact holes H and a plurality of first contact holes CH1 and H1-1 to H1-16 may be defined in the first connecting pattern SDP1. The first contact hole CH1 may be the first contact hole CH1 illustrated in FIG. 7. The contact holes H and the first contact holes H1-1 to H1-16 may be formed similarly to the first contact hole CH1.

The first connecting electrode CNE1 may be connected to the sixth drain area D6 of the sixth transistor T6 through the first contact hole CH1. The first connecting electrode CNE1 may be connected to the second connecting electrode CEN2 illustrated in FIG. 8E.

A portion of the repair line RL may overlap a portion of the first connecting electrode CNE1. When the first pixel circuit PC1 is damaged and is not driven, the repair line RL may be connected to the first connecting electrode CNE1 by a laser. Although not illustrated, a dummy pixel circuit may be disposed in the above-described non-display area NDA. The dummy pixel circuit may be connected to the repair line RL. Accordingly, when the first pixel circuit PC1 is damaged, the dummy pixel circuit connected to the repair line RL may be used.

The bias scan line GBL may include the connecting line CL. The connecting line CL may extend in the first direction DR1. The connecting line CL may be disposed between the first pixel circuit PC1 and the second pixel circuit PC2.

The connecting line CL may be connected to the sub-bias scan lines SBL through the contact holes H overlapping the connecting line CL. The sub-bias scan lines SBL separated from each other may be electrically connected with each other by the connecting line CL.

The first connecting electrode CE1-1 may be connected to the fifth source area S5 of the fifth transistor T5, the dummy electrode DME, and the first dummy electrode DME1 through the first contact holes H1-1 overlapping the first connecting electrode CE1-1. The first connecting electrode CE1-1 may be connected to the first dummy electrode DME1 through the first contact hole H1-1 overlapping the second opening OP2.

Since the second drain area D2 of the second transistor T2 extends from the fifth source area S5, the second transistor T2 may also be connected to the first dummy electrode DME1 by the first connecting electrode CE1-1.

The first connecting electrode CE1-2 may be connected to the second dummy electrode DME2 through the first contact hole H1-2 overlapping the first connecting electrode CE1-2. The first connecting electrode CNE1-3 may be connected to the second source area S2 of the second transistor T2 through the first contact hole H1-3 overlapping the first connecting electrode CE1-3.

The first connecting electrode CE1-4 may be connected to the first gate electrode G1 of the first transistor Tl and the fourth source area S4 of the fourth transistor T4 through the first contact holes H1-4 overlapping the first connecting electrode CE1-4. The first connecting electrode CE1-4 may be connected to the first gate electrode G1 through the first contact hole H1-4 overlapping the first opening OP1. The first transistor T1 and the fourth transistor T4 may be connected with each other by the first connecting electrode CE1-4.

Since the third drain area D3 of the third transistor T3 extends from the fourth source area S4, the third transistor T3 may also be connected to the first transistor T1 by the first connecting electrode CE1-4.

The first connecting electrode CE1-5 may be connected to the ninth gate electrode G9 of the ninth transistor T9 and the first light emission line EML1 through the first contact holes H1-5 overlapping the first connecting electrode CE1-5. The first connecting electrode CE1-6 may be connected to the fourth drain area D4 of the fourth transistor T4 and the first initialization line VIL1 through the first contact holes H1-6 overlapping the first connecting electrode CE1-6.

The first connecting electrode CE1-7 may be connected to the ninth source area S9 of the ninth transistor T9 through the first contact hole H1-7 overlapping the first connecting electrode CE1-7. The first connecting electrode CE1-8 may be connected to the sixth gate electrode G6 of the sixth transistor T6 and the second light emission line EML2 through the first contact holes H1-8 overlapping the first connecting electrode CE1-8. The first connecting electrode CE1-9 may be connected to the eighth source area S8 of the eighth transistor T8 and the bias line VBL through the first contact holes H1-9 overlapping the first connecting electrode CE1-9.

The write scan line GWL may be connected to the second gate electrode G2 of the second transistor T2 through the first contact hole H1-10. One compensation scan line GCL may be connected to the fifth gate electrode G5 of the fifth transistor T5 through the first contact hole H1-11.

The reference line VL may be connected to the fifth drain area D5 of the fifth transistor T5 through the first contact hole H1-12. The initialization scan line GIL may be connected to the fourth gate electrode G4 of the fourth transistor T4 through the first contact hole H1-13. Another compensation scan line GCL may be connected to the third gate electrode G3 of the third transistor T3 through the first contact hole H1-14.

The second initialization line VIL2 disposed between the bias scan line GBL and the bias line VBL may be connected to the seventh drain area D7 of the seventh transistor T7 through the first contact hole H1-15. The second initialization line VIL2 disposed between the repair line RL and the bias scan line GBL may be connected to the seventh drain area D7 of the seventh transistor T7 of the second pixel circuit PC2 through the first contact hole H1-16.

In FIG. 8E, the reference numerals of the first connecting electrodes CNE1 and CE1-1 to CE1-9, the first contact holes CH1 and H1-1 to H1-16, the contact holes H, and the first and second openings OP1 and OP2 are omitted, and the omitted reference numerals of the first connecting electrodes CNE1 and CE1-1 to CE1-9, the first contact holes CH1 and H1-1 to H1-16, and the contact holes H are referred to those shown in FIG. 8D.

Referring to FIG. 8E, a second connecting pattern SDP2 may be disposed on the first connecting pattern SDP1. The second connecting pattern SDP2 may be defined as a second source-drain pattern.

The second connecting pattern SDP2 may include the second connecting electrode CNE2, a data line DL, the first power line PL1, a reference line VL′, and a second initialization line VIL2′. The second connecting electrode CNE2 may be the second connecting electrode CEN2 illustrated in FIG. 7. The data line DL, the first power line PL1, the reference line VL′, and the second initialization line VIL2′ may extend in the second direction DR2 and may be arranged in the first direction DR1.

The data line DL, the first power line PL1, the reference line VL′, and the second initialization line VIL2′ may be disposed in (or directly on) a same layer as the second connecting electrode CNE2. The data line DL, the first power line PL1, the reference line VL′, and the second initialization line VIL2′ may be simultaneously subjected to patterning with a same material as that of the second connecting electrode CNE2.

The first power line PL1 may be disposed between the data line DL and the reference line VL′. The second initialization line VIL2′ may overlap the third pixel circuit PC3.

A plurality of second contact holes CH2 and H2-1 to H2-5 may be defined in the second connecting pattern SDP2. The second contact hole CH2 may be the second contact hole CH2 illustrated in FIG. 7. The second contact holes H2-1 to H2-5 may be formed similarly to the second contact hole CH2.

The second connecting electrode CNE2 may be connected to the first connecting electrode CNE1 through the second contact hole CH2. The second connecting electrode CNE2 may be connected to the first electrode AE illustrated in FIG. 7 through the third contact hole CH3. For convenience of illustration, the first electrode AE is omitted in the layout diagram of the pixel PX. The first electrode AE may be connected to the sixth transistor T6 through the first and second connecting electrodes CNE1 and CNE2.

The sixth semiconductor layer S6, A6, and D6 of the sixth transistor T6 may extend to the first drain area D1, and the sixth drain area D6 may be connected to the first electrode AE. Accordingly, the first drain area D1 may be connected to the light emitting element OLED.

The data line DL may be connected to the first connecting electrode CE1-3 through the second contact hole H2-1. The data line DL may be connected to the second transistor T2 through the first connecting electrode CE1-3.

The first power line PL1 may be connected to the first connecting electrode CE1-2 through the second contact hole H2-2. The first power line PL1 may be connected to the second dummy electrode DME2 through the first connecting electrode CE1-2. The first power line PL1 may be connected to the first connecting electrode CE1-7 through the second contact hole H2-3. The first power line PL1 may be connected to the ninth transistor T9 through the first connecting electrode CE1-7. Accordingly, the ninth transistor T9 and the second capacitor C2 may be connected to the first power line PL1.

The first voltage may be applied to the second dummy electrode DME2 through the first power line PL1. That is, a constant voltage may be applied to the second dummy electrode DME2. As described above, the second dummy electrode DME2 may overlap portions of the semiconductor pattern SMP of the third and fourth transistors T3 and T4. When the constant voltage is applied to the second dummy electrode DME2, the threshold voltage Vth of each of the third and fourth transistors T3 and T4 overlapping the second dummy electrode DME2 may be maintained without being changed.

The reference line VL′ may be defined as a vertical reference line. The reference line VL′ may be connected to the reference line VL through the second contact hole H2-4. The reference voltage VR may be applied to the reference line VL through the reference line VL′.

The second initialization line VIL2′ may be connected to the second initialization line VIL2 adjacent to the lower side of the first pixel circuit PC1 through the second contact hole H2-5. The second initialization voltage VAINT may be applied to the second initialization line VIL2′ and the second initialization lines VIL2.

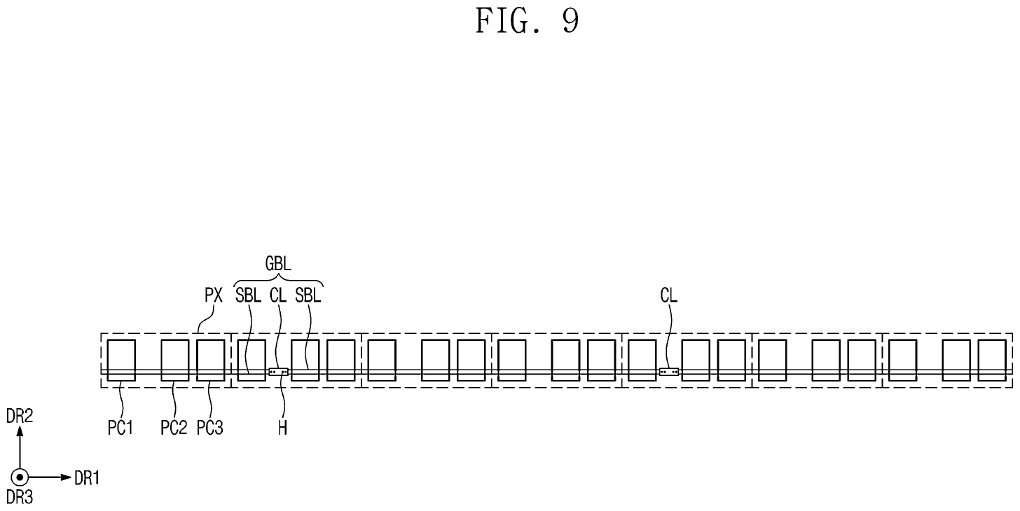

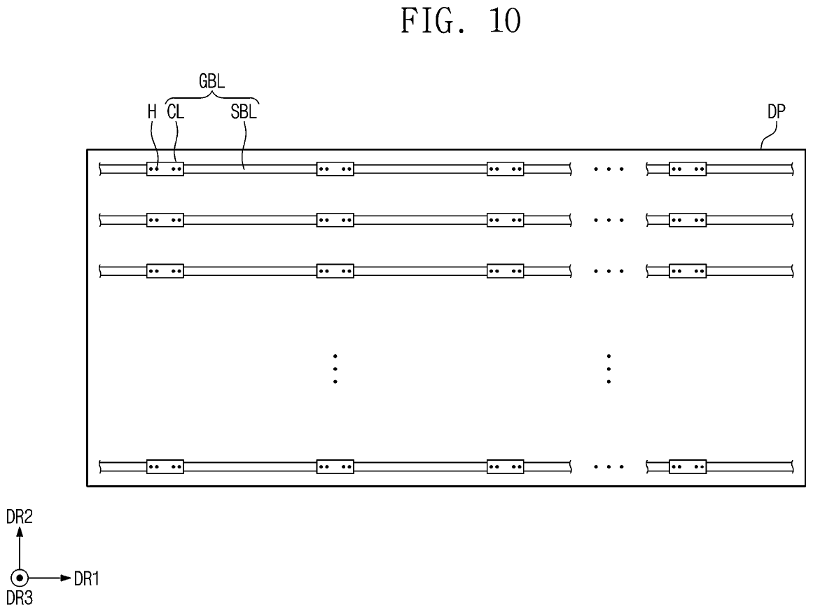

FIG. 9 is a schematic plan view illustrating pixels arranged in one row and a bias scan line. FIG. 10 is a view illustrating only a plurality of bias scan lines in the display panel.

In FIG. 9, the first, second, and third pixel circuits PC1, PC2, and PC3 are illustrated in a rectangular shape, and the pixels PX are separated by rectangular dotted lines.

Referring to FIGS. 9 and 10, in an embodiment of the display panel DP, the bias scan lines GBL may extend in the first direction DR1 and may be arranged in the second direction DR2. In each of the bias scan lines GBL, a plurality of connecting lines CL and more than two sub-bias scan lines SBL may be provided. That is, each of the bias scan lines GBL may include a plurality of connecting lines CL and a plurality of sub-bias scan lines SBL.

The pixels PX may be arranged in the first direction DR1. The connecting lines CL and the sub-bias scan lines SBL may extend in the first direction DR1 and may be arranged in the first direction DR1.

Each of the pixels PX may include the first pixel circuit PC1, the second pixel circuit PC2, and the third pixel circuit PC3. The first, second, and third pixel circuits PC1, PC2, and PC3 may correspond to those illustrated in FIGS. 8A to 8E.

In an embodiment, one connecting line CL may be disposed every three pixels PX. The sub-bias scan lines SBL may be spaced apart from each other every three pixels PX and may be connected by the connecting lines CL. That is, the connecting line CL may be disposed in each of the h-th pixel PX and the (h+3)-th pixel PX, and in each of the h-th pixel PX and the (h+3)-th pixel PX, the sub-bias scan lines SBL may be spaced apart from each other and may be connected by the connecting line CL. Here, “h” is a natural number.

FIGS. 11 and 12 are views illustrating components of bias scan lines according to embodiments of the disclosure.

FIGS. 11 and 12 are plan views corresponding to FIG. 9. Hereinafter, the components illustrated in FIGS. 11 and 12 will be described focusing on the difference from the components illustrated in FIG. 9.

Referring to FIG. 11, in an embodiment, one connecting line CL may be disposed every two pixels PX. Sub-bias scan lines SBL may be spaced apart from each other every two pixels PX and may be connected by the connecting line CL. That is, the connecting line CL may be disposed in each of the h-th pixel PX and the (h+2)-th pixel PX, and in each of the h-th pixel PX and the (h+2)-th pixel PX, the sub-bias scan lines SBL may be spaced apart from each other and may be connected by the connecting line CL.

Referring to FIG. 12, in another embodiment, one connecting line CL may be disposed for each pixel PX. Sub-bias scan lines SBL may be spaced apart from each other for each pixel PX and may be connected by the connecting line CL.

Referring to FIGS. 9, 11, and 12, in an embodiment, the sub-bias scan lines SBL may be spaced apart from each other for a predetermined number of pixels PX, and each of the connecting lines CL may be disposed for the predetermined number of pixels PX and may connect the sub-bias scan lines SBL.

Embodiments of the disclosure are not limited to the configurations illustrated in FIGS. 9, 11, and 12. In another embodiment, for example, sub-bias scan lines SBL may be spaced apart from each other every four or more pixels PX, and each of connecting lines CL may be disposed every four or more pixels PX to connect the sub-bias scan lines SBL.

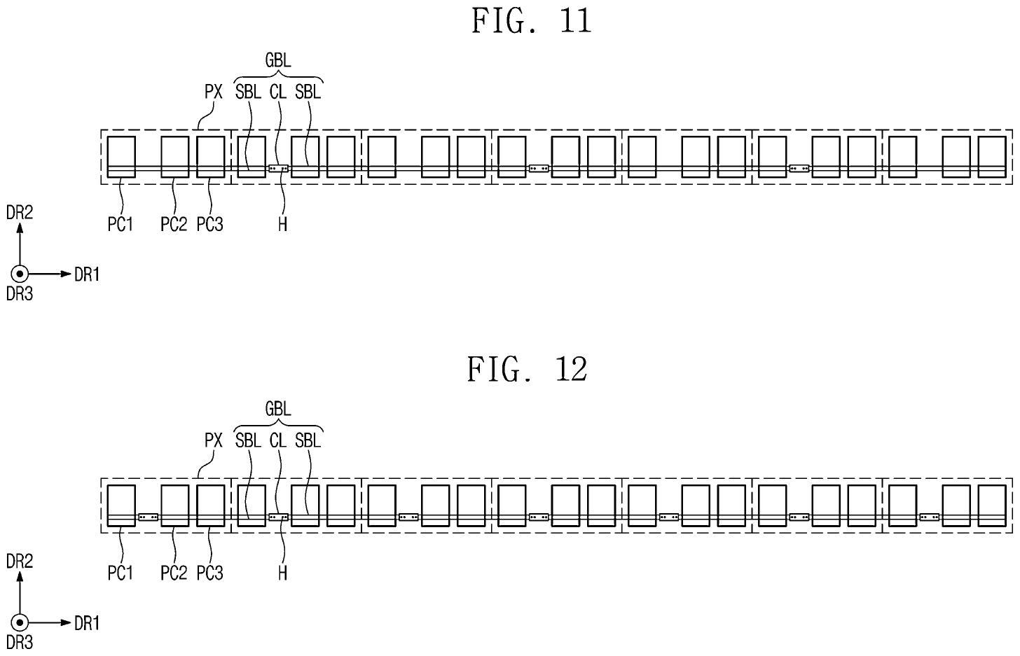

FIG. 13 is a sectional view taken along line I-I′ illustrated in FIG. 8D.

Referring to FIG. 13, the seventh and eighth channel areas A7 and A8 may be disposed on the buffer layer BFL. The first insulating layer INS1 may be disposed on the seventh and eighth channel areas A7 and A8 and the buffer layer BFL.

The sub-bias scan lines SBL may be disposed on the first insulating layer INS1 and may be spaced apart from each other at an area or region between the seventh and eighth channel areas A7 and A8. The second insulating layer INS2 and the third insulating layer INS3 may be disposed on the sub-bias scan lines SBL and the first insulating layer INS1.

The connecting line CL may be disposed on the third insulating layer INS3. The connecting line CL may be connected to the sub-bias scan lines SBL through the contact holes H defined in the second and third insulating layers INS2 and INS3. The fourth insulating layer INS4 and the fifth insulating layer INS5 may be disposed on the connecting line CL and the third insulating layer INS3.

The connecting line CL may be disposed in (or directly on) a layer different from the layer in which the sub-bias scan lines SBL are disposed and may be connected to the sub-bias scan lines SBL. In an embodiment, for example, the connecting line CL may be disposed above the sub-bias scan lines SBL and may be connected to the sub-bias scan lines SBL. Accordingly, the connecting lines CL illustrated in FIGS. 9 and 10 may be disposed above the sub-bias scan lines SBL and may be connected to the sub-bias scan lines SBL.

Referring to FIGS. 7 and 13, the connecting line CL may be disposed in (or directly on) a same layer as the first connecting electrode CNE1. The sub-bias scan lines SBL may be disposed in (or directly on) a same layer as the gate electrodes G1 and G6. Accordingly, the connecting line CL may be disposed above the gate electrodes G1 and G6.

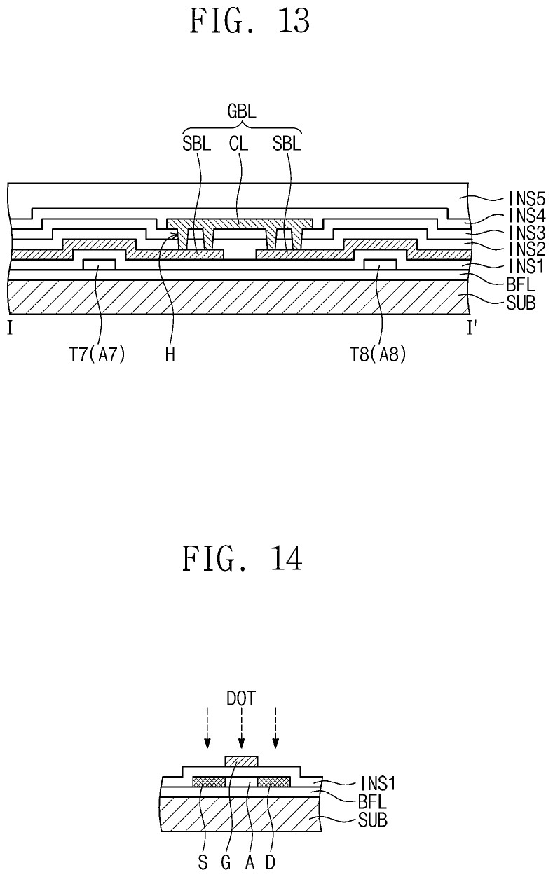

FIG. 14 is a view for explaining a doping process for a semiconductor layer.

The gate electrode G and the semiconductor layer S, A, and D illustrated in FIG. 14 may be the gate electrode and the semiconductor layer of one of the first to ninth transistors T1 to T9.

Referring to FIG. 14, in an embodiment, the doping process may be performed on the semiconductor layer S, A, and D after the gate electrode G is provided (or formed) on the first insulating layer INS1. A dopant DOT may be provided to the source area S and the drain area D with the gate electrode G as a mask. Accordingly, the source area S and the drain area D may be formed to be highly doped areas.

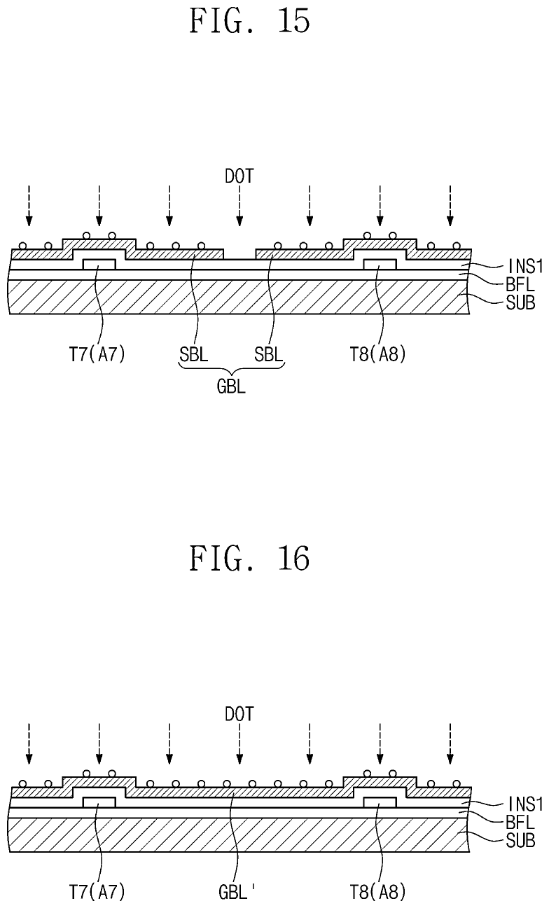

FIG. 15 is a view illustrating a doping process performed in a state in which sub-bias scan lines of the disclosure are disposed on a substrate. FIG. 16 is a view illustrating a doping process performed in a state in which a comparative bias scan line is disposed on a substrate.

Referring to FIGS. 15 and 16, the comparative bias scan line GBL′ may be formed of a single line without being divided into the sub-bias scan lines SBL like the bias scan line GBL according to an embodiment.

In the doping processes, a phenomenon in which charges are concentrated on the bias scan line GBL and the comparative bias scan line GBL' may occur. For example, the charges are illustrated in a circular shape in FIGS. 15 and 16.

When a single line, such as the comparative bias scan line GBL′, is disposed on the substrate SUB, more charges may be concentrated on the comparative bias scan line GBL′. Depending on the concentration of charges, static electricity may be generated. The static electricity may damage the seventh and eighth channel areas A7 and A8, which are semiconductor layers. For example, the seventh and eighth channel areas A7 and A8, which are semiconductor layers, may be burnt by the static electricity generated due to the concentration of charges. Therefore, the transistors T7 and T8 may be damaged so that the pixel PX may be damaged.

In an embodiment of the disclosure, the bias scan line GBL may be divided into the plurality of sub-bias scan lines SBL, and thus the concentration of charges may be dispersed to the sub-bias scan lines SBL in the doping process. Accordingly, static electricity generated from the bias scan line GBL may be reduced, and damage to the pixels PX may be effectively prevented.

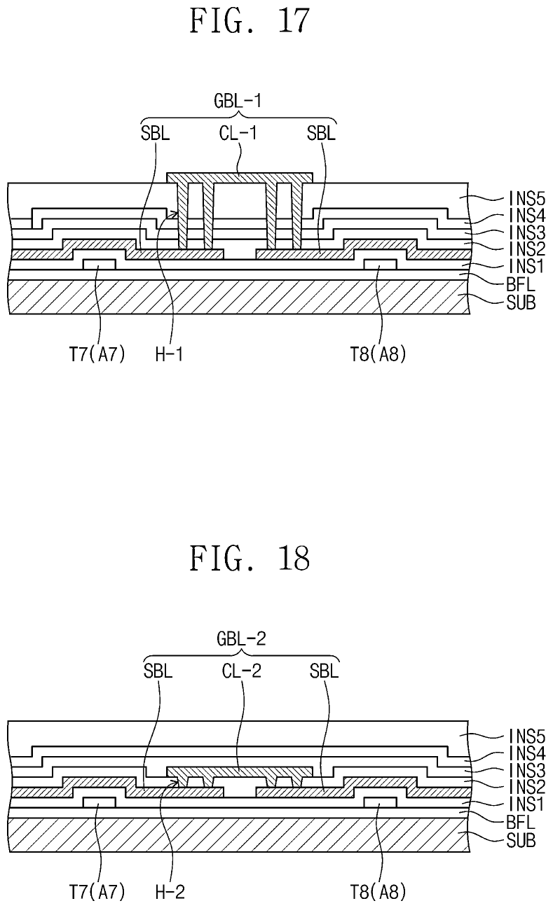

FIGS. 17 to 19 are views illustrating components of bias scan lines according to various embodiments of the disclosure.

FIGS. 17 to 19 are sectional views corresponding to FIG. 13. Hereinafter, the components illustrated in FIGS. 17 to 19 will be described focusing on the difference from the components illustrated in FIG. 13.

Referring to FIGS. 7 and 17, in an embodiment, a bias scan line GBL-1 may include a plurality of sub-bias scan lines SBL and a connecting line CL-1. The connecting line CL-1 may be disposed on the fifth insulating layer INS5. Accordingly, the connecting line CL-1 may be disposed in (or directly on) a same layer as the second connecting electrode CNE2. The connecting line CL-1 may be connected to the sub-bias scan lines SBL through contact holes H-1 defined in the second to fifth insulating layers INS2 to INS5.

Referring to FIGS. 7 and 18, in another embodiment, a bias scan line GBL-2 may include a plurality of sub-bias scan lines SBL and a connecting line CL-2. The connecting line CL-2 may be disposed on the second insulating layer INS2. Accordingly, the connecting line CL-2 may be disposed in (or directly on) a same layer as the dummy electrode DME. The connecting line CL-2 may be connected to the sub-bias scan lines SBL through contact holes H-2 defined in the second insulating layer INS2.

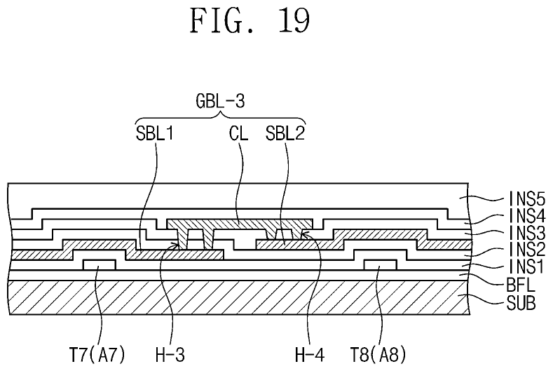

Referring to FIGS. 7 and 19, in another embodiment, a bias scan line GBL-3 may include a plurality of sub-bias scan lines SBL1 and SBL2 and a connecting line CL. The connecting line CL may be disposed on the third insulating layer INS3.

The sub-bias scan lines SBL1 and SBL2 may be disposed in (or directly on) different layers, respectively. In an embodiment, for example, the sub-bias scan lines SBL1 and SBL2 may include the first sub-bias scan line SBL1 disposed in (or directly on) a same layer as the gate electrodes G1 and G6 and the second sub-bias scan line SBL2 disposed in (or directly on) a same layer as the dummy electrode DME.

The connecting line CL may be connected to the first sub-bias scan line SBL1 through contact holes H-3 defined in the second and third insulating layers INS2 and INS3. The connecting line CL may be connected to the second sub-bias scan line SBL2 through contact holes H-4 defined in the third insulating layer INS3.

According to the embodiments of the disclosure, the bias scan line may be divided into the plurality of sub-bias scan lines, and thus the concentration of charges may be dispersed to the sub-bias scan lines in the doping process. Accordingly, the static electricity generated from the bias scan line may be reduced, and damage to the pixels may be effectively prevented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a scan line extending in a first direction, wherein the scan line includes a write scan line and a bias scan line;
a data line extending in a second direction crossing the first direction; and
a pixel connected to the scan line and the data line,
wherein the bias scan line includes:
a plurality of sub-bias scan lines spaced apart from each other in the first direction; and
a connecting line connected to the sub-bias scan lines.

2. The display device of claim 1, wherein the connecting line is disposed in a layer different from a layer in which the sub-bias scan lines are disposed.

3. The display device of claim 2, wherein the connecting line is disposed above the sub-bias scan lines.

4. The display device of claim 1, wherein the pixel includes:
a first pixel circuit, a second pixel circuit, and a third pixel circuit, which are arranged in the first direction; and
light emitting elements connected to the first, second, and third pixel circuits, respectively.

5. The display device of claim 4, wherein a gap between the first pixel circuit and the second pixel circuit in the first direction is greater than a gap between the second pixel circuit and the third pixel circuit in the first direction.

6. The display device of claim 5, wherein the connecting line is disposed between the first pixel circuit and the second pixel circuit.

7. The display device of claim 1, wherein
the data line is provided in plural,
the pixel is provided in plural,
the connecting line is provided in plural, and
the sub-bias scan lines include three or more sub-bias scan lines, and
wherein a plurality of pixels, a plurality of connecting lines, and the three or more sub-bias scan lines are arranged in the first direction.

8. The display device of claim 7, wherein
the connecting lines are disposed one by one every three pixels, and
the three or more sub-bias scan lines are spaced apart from each other every three pixels and connected to each other by the connecting lines.

9. The display device of claim 7, wherein
the connecting lines are disposed one by one every two pixels, and
the three or more sub-bias scan lines are spaced apart from each other every two pixels and connected to each other by the connecting lines.

10. The display device of claim 7, wherein
the connecting lines are disposed one by one for each pixel, and
the three or more sub-bias scan lines are spaced apart from each other for each pixel and connected to each other by the connecting lines.

11. The display device of claim 1, wherein the pixel includes:
a plurality of transistors connected to the data line, the write scan line, and the bias scan line; and
a light emitting element connected to a corresponding transistor among the transistors,
wherein each of the transistors includes:
a semiconductor layer including a source area, a channel area, and a drain area; and
a gate electrode disposed over the semiconductor layer, and
wherein the sub-bias scan lines are disposed in a same layer as the gate electrode.

12. The display device of claim 11, wherein the connecting line is disposed above the gate electrode.

13. The display device of claim 11, wherein the pixel further includes:
a dummy electrode disposed over the gate electrode;
a first connecting electrode disposed above the dummy electrode and connected to a corresponding transistor among the transistors; and
a second connecting electrode disposed over the first connecting electrode and connected to the first connecting electrode, and
wherein the light emitting element is disposed over the second connecting electrode and connected to the second connecting electrode.

14. The display device of claim 13, wherein the connecting line is disposed in a same layer as the first connecting electrode.

15. The display device of claim 13, wherein the connecting line is disposed in a same layer as the second connecting electrode.

16. The display device of claim 13, wherein the connecting line is disposed in a same layer as the dummy electrode.

17. The display device of claim 1, wherein the sub-bias scan lines are disposed in different layers, respectively.

18. A display device comprising:
a scan line extending in a first direction, wherein the scan line includes a write scan line and a bias scan line;
a plurality of data lines extending in a second direction crossing the first direction; and
a plurality of pixels arranged in the first direction and connected to the scan line and the data lines,
wherein the bias scan line includes:
a plurality of sub-bias scan lines spaced apart from each other for at least one pixel; and
a plurality of connecting lines connected to the sub-bias scan lines.

19. The display device of claim 18, wherein the connecting lines are disposed above the sub-bias scan lines and connected to the sub-bias scan lines.

20. A display device comprising:
a scan line extending in a first direction, wherein the scan line includes a write scan line and a bias scan line;
a data line extending in a second direction crossing the first direction; and
a pixel connected to the scan line and the data line,
wherein the bias scan line includes:
two sub-bias scan lines spaced apart from each other in the first direction; and
a connecting line connected to the two sub-bias scan lines,
wherein the pixel includes:
a plurality of transistors connected to the data line, the write scan line, and the bias scan line; and
a light emitting element connected to a corresponding transistor among the transistors, and
wherein
the two sub-bias scan lines are disposed in a same layer as gate electrodes of the transistors, and
the connecting line is disposed above the gate electrodes.
